(19) United States
(12) Patent Application Publication
(10) Pub. No.: US 2018/0228059 A1
(43) Pub. Date: Aug. 9, 2018

(54) ELECTRONIC APPARATUS AND COOLING CONTROL APPARATUS AND COOLING CONTROL METHOD FOR THE SAME

(71) Applicant: FUJITSU LIMITED, Kawasaki-shi (JP)

(72) Inventors: Akira MATSUO, Kawasaki (JP); Hitoshi Suzuki, Oyama (JP)

(73) Assignee: FUJITSU LIMITED, Kawasaki-shi (JP)

(21) Appl. No.: 15/879,855

(22) Filed: Jan. 25, 2018

(30) Foreign Application Priority Data
Feb. 3, 2017 (JP) 2017-018920

(51) Int. Cl. H05K 7/20; G06F 1/20

(52) U.S. Cl. CPC H05K 7/20772; F28D 15/0275; H05K 7/20645; G06F 1/20

(57) ABSTRACT

A cooling control apparatus for an electronic apparatus in which a plurality of electronic units to be cooled are housed, the cooling control apparatus includes a pump controller that controls a pump based on a detection value of a parameter indicating a flow rate of liquid refrigerant in one passage, among a plurality of passages, in a state in which the refrigerant for cooling the plurality of electronic units are discharged from the pump and is supplied to the plurality of passages via a supply manifold.

### CROSS-REFERENCE TO RELATED APPLICATION

This application is based upon and claims the benefit of priority of the prior Japanese Patent Application No. 2017-18920, filed on Feb. 3, 2017, the entire contents of which are incorporated herein by reference.

### FIELD

The embodiments discussed herein are related to an electronic apparatus and a cooling control apparatus and a cooling control method for the electronic apparatus.

### BACKGROUND

Technologies to cool multiple electronic units to be cooled with liquid refrigerant are known.

However, with the above technologies, it is difficult to stably supply the refrigerant at a desired flow rate to each of the multiple electronic units without using many flowmeters. For example, if part of the multiple electronic units is removed or a new electronic unit is added, the supply flow rate to each electronic unit is significantly varied from the desired flow rate even when the discharge rate of a pump is fixed.

The followings are reference documents.

[Document 1] Japanese Laid-open Patent Publication No. 2005-228216, and

[Document 2] Japanese Laid-open Patent Publication No. 2005-73400.

### SUMMARY

According to an aspect of the invention, a cooling control apparatus for an electronic apparatus in which a plurality of electronic units to be cooled are housed, the cooling control apparatus includes a pump controller that controls a pump based on a detection value of a parameter indicating a flow rate of liquid refrigerant in one passage, among a plurality of passages, in a state in which the refrigerant for cooling the plurality of electronic units are discharged from the pump and is supplied to the plurality of passages via a supply manifold.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an exemplary front view illustrating an electronic apparatus according to a first embodiment;

FIG. 2 is an exemplary perspective view illustrating a water cooling unit and a bookshelf-type unit;

FIG. 3 is a perspective view schematically illustrating an example of the bookshelf-type unit;

FIG. 4 is an explanatory drawing of the outline of a cooling system in the electronic apparatus according to the first embodiment;

FIG. 5 is an explanatory drawing of a cooling control system in the electronic apparatus according to the first embodiment;

FIG. 6 is a table illustrating an example of the relationship between flow rate ratios and power consumption;

FIG. 7A illustrates an exemplary hardware configuration of a control unit;

FIG. 7B schematically illustrates an exemplary functional configuration of the control unit;

FIG. 8 is a flowchart schematically illustrating an exemplary process realized by a pump rotation speed controlling portion;

FIG. 9 is an explanatory drawing of the cooling control system in an electronic apparatus according to a second embodiment;

FIG. 10 is an explanatory drawing of the cooling control system in an electronic apparatus according to a third embodiment;

FIG. 11 is an explanatory drawing of the cooling control system in an electronic apparatus according to a fourth embodiment;

FIG. 12 is an explanatory drawing of the cooling control system in an electronic apparatus according to a fifth embodiment;

FIG. 13 is a table illustrating an example of the relationship between the valve openings of regulating valves and the flow rate ratios;

FIG. 14 is a diagram illustrating an image of the content of control by a regulating valve controller;

FIG. 15 is a flowchart illustrating an exemplary process performed by a bookshelf-type unit side controller; and

FIG. 16 is a flowchart illustrating an exemplary process performed by the regulating valve controller in the control unit.

### DESCRIPTION OF EMBODIMENTS

Embodiments will herein be described in detail with reference to the drawings.

### First Embodiment

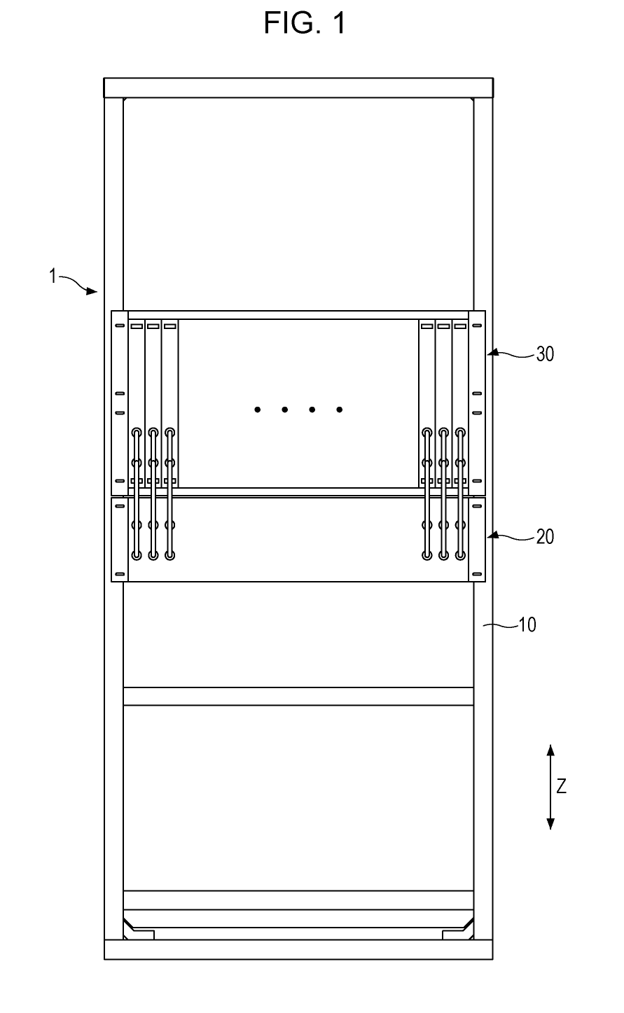

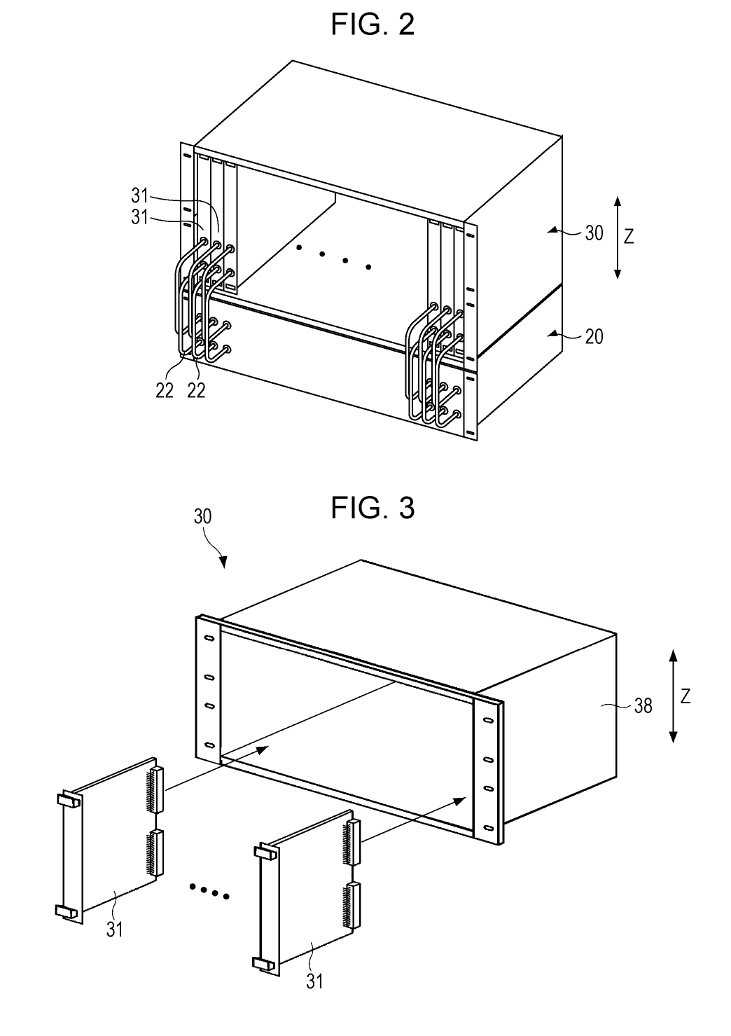

FIG. 1 is an exemplary front view illustrating an electronic apparatus 1 according to a first embodiment. FIG. 2 is an exemplary perspective view illustrating a water cooling unit 20 and a bookshelf-type unit 30. The Z-axis direction is defined in FIG. 1. The Z-axis direction corresponds to the height direction.

The electronic apparatus 1 is an apparatus in which multiple electronic units 31 are housed and is a liquid cooling apparatus in which the electronic units 31 are cooled with liquid refrigerant. The liquid refrigerant may be antifreeze containing, for example, propylene glycol. The electronic apparatus 1 composes a base station apparatus for wireless communication as an example. The electronic apparatus 1 may be disposed outside or may be disposed inside. In a modification, the electronic apparatus 1 may have a mode of another electronic apparatus, such as a server or a supercomputer.

The electronic apparatus 1 includes a rack 10, the water cooling unit 20, and the bookshelf-type unit 30.

The rack 10 forms a supporting frame for the entire electronic apparatus 1. The water cooling unit 20 and the bookshelf-type unit 30 are installed in the rack 10. Although one pair of the water cooling unit 20 and the bookshelf-type unit 30 is installed in the rack 10 in the example illustrated in FIG. 1, multiple pairs of the water cooling unit 20 and the bookshelf-type unit 30 may be installed in the rack 10. In addition, although one water cooling unit 20 is provided for one bookshelf-type unit 30 as an example in the first embodiment, a configuration in which one water cooling unit is provided for multiple bookshelf-type units or a configuration in which multiple water cooling units are provided for one bookshelf-type unit may be adopted.

The water cooling unit 20 cools each electronic unit 31 in the bookshelf-type unit 30 with the liquid refrigerant (secondary refrigerant).

The bookshelf-type unit 30 houses the respective electronic units 31 in a mode of a “bookshelf”. Accordingly, each electronic unit 31 may have a mode of a card in which an electronic device is housed and may be referred to as a plug-in unit (PIU).

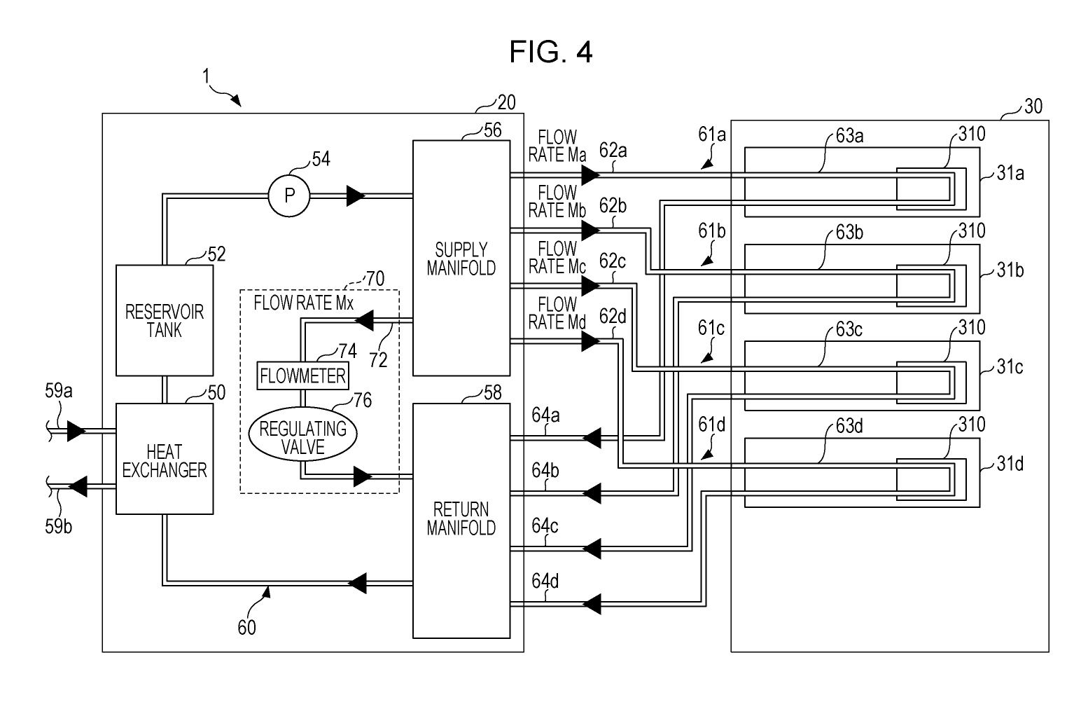

The electronic units 31 realize various functions of the base station apparatus. Each of the electronic unit 31 to be cooled includes a device (heating element), such as a processing unit. The electronic units 31 to be cooled include passages (refer to passages 63a to 63d in FIG. 4) through which the secondary refrigerant passes to build a structure capable of emitting heat of the device to the outside. The passages in the electronic units 31 may have an arbitrary structure. For example, in each of the electronic units 31, the passage of the secondary refrigerant may be formed in an aspect in which the passage is in contact with a radiator unit (a cold plate for liquid cooling) (refer to a radiator unit 310 in FIG. 4) thermally connected to the device or in an aspect in which the passage passes through the radiator unit.

The respective electronic units 31 to be cooled communicate with the water cooling unit 20 with pipes 22, as illustrated in FIG. 2. The pipes 22 include pipes for supplying the secondary refrigerant (refer to supply connection passages 62a to 62d in FIG. 4) and pipes for returning the secondary refrigerant (refer to return connection passages 64a to 64d in FIG. 4).

FIG. 3 is a perspective view schematically illustrating an example of the bookshelf-type unit 30. As illustrated in FIG. 3, the bookshelf-type unit 30 includes a rack mount chassis 38. The rack mount chassis 38 is fixed to the rack 10. Multiple slot portions are formed in the rack mount chassis 38, as illustrated in FIG. 3. The electronic unit 31 is inserted into each slot portion to be housed in the electronic apparatus 1. An aspect of how the multiple electronic units 31 are inserted is indicated by arrows in FIG. 3. Although all the multiple electronic units 31 may have the same configuration realizing the same function, the multiple electronic units 31 generally include a unit (units) realizing a different function (different functions). Accordingly, the multiple electronic units 31 may have different sizes.

In general, many electronic units 31 are housed in one bookshelf-type unit 30 in the electronic apparatus 1 composing the base station apparatus. The number of the electronic units 31 is, for example, 30 to 50 in the case of the bookshelf-type unit 30 of about 8U (1U=1.75 inches=44.45 mm). This is a contrast to, for example, a server in which about 30 electronic units are provided per rack.

A cooling system in the electronic apparatus 1 will now be described with reference to FIG. 4.

FIG. 4 is an explanatory drawing of the outline of the cooling system in the electronic apparatus 1. Referring to FIG. 4, the passages are indicated by double lines and the directions in which the refrigerant flows are indicated by arrows on the passages. Only four electronic units 31 are illustrated in FIG. 4. However, many electronic units 31 may be practically provided, as described above. The four electronic units 31 are hereinafter referred to as electronic units 31a to 31d when the four electronic units 31 are discriminated from each other. The radiator unit 310 in each electronic unit 31 is schematically illustrated in FIG. 4.

The cooling system in the electronic apparatus 1 includes a heat exchanger 50, a reservoir tank 52, a pump 54, a supply manifold 56, a return manifold 58, and a water cooling unit passage 60. The cooling system in the electronic apparatus 1 also includes the supply connection passages 62a to 62d, the passages 63a to 63d in the electronic units 31a to 31d, respectively, the return connection passages 64a to 64d, and a flow rate monitoring unit 70.

The heat exchanger 50, the reservoir tank 52, the pump 54, the supply manifold 56, the return manifold 58, the water cooling unit passage 60, and the flow rate monitoring unit 70 are provided in the water cooling unit 20. However, part of these components may be provided outside the water cooling unit 20.

The heat exchanger 50 performs heat exchange between primary refrigerant and the secondary refrigerant. The primary refrigerant is supplied from a chiller or a radiator (not illustrated) outside the electronic apparatus 1 through a passage 59a and is returned to the chiller or the radiator through a passage 59b. Although the heat exchange is realized between the liquid primary refrigerant and the liquid secondary refrigerant in the heat exchanger 50, heat exchange may be further realized between the air outside the electronic apparatus 1 and the secondary refrigerant in the heat exchanger 50.

The reservoir tank 52 stores the secondary refrigerant.

The pump 54 is provided between the reservoir tank 52 and the supply manifold 56. The pump 54 sucks and discharges the secondary refrigerant in the reservoir tank 52 during operation. The pump 54 has a variable discharge rate. The pump 54 is, for example, an electrically powered pump.

The supply manifold 56 is a member that is also referred to as a header. The supply manifold 56 stores the secondary refrigerant for branch supply, which is discharged from the pump 54. The supply connection passages 62a to 62d are connected to the supply manifold 56 and a monitoring control passage 72 in the flow rate monitoring unit 70 described below is also connected to the supply manifold 56. Accordingly, the secondary refrigerant in the supply manifold 56 is distributed and supplied to the supply connection passages 62a to 62d and the monitoring control passage 72.

The return manifold 58 is a member that is also referred to as a header. The return manifold 58 collects and stores the secondary refrigerant to be returned to the heat exchanger 50. The return connection passages 64a to 64d are connected to the return manifold 58 and the monitoring control passage 72 in the flow rate monitoring unit 70 described below is also connected to the return manifold 58. Accordingly, the secondary refrigerant supplied through the supply connection passages 64a to 64d and the monitoring control passage 72 is collected in the return manifold 58.

The water cooling unit passage 60 is a passage connected to the heat exchanger 50, the reservoir tank 52, the pump 54, the supply manifold 56, and the return manifold 58. The water cooling unit passage 60 cooperates with the supply connection passages 62a to 62d, the passages 63a to 63d in the electronic units 31a to 31d, respectively, and the return connection passages 64a to 64d to form a circular passage of the secondary refrigerant.

Specifically, the secondary refrigerant from the heat exchanger 50 is stored in the reservoir tank 52 and is supplied from the reservoir tank 52 to the supply manifold 56 with the pump 54. The secondary refrigerant is supplied from the supply manifold 56 to the passages 63a to 63d in the electronic units 31a to 31d through the supply connection passages 62a to 62d, respectively. The secondary refrigerant is returned from the passages 63a to 63d to the return manifold 58 through the return connection passages 64a to 64d, respectively. The secondary refrigerant is returned from the return manifold 58 to the heat exchanger 50 through the water cooling unit passage 60 (the return side) again. The secondary refrigerant circulates around the cooling system in the above manner while receiving the heat in each electronic unit 31 and discharging the heat in the heat exchanger 50. However, part of the secondary refrigerant from the supply manifold 56 is returned to the return manifold 58 through the monitoring control passage 72 in the flow rate monitoring unit 70 in the first embodiment. Accordingly, all the secondary refrigerant from the supply manifold 56 does not circulate through the bookshelf-type unit 30.

The supply connection passages 62a to 62d, the return connection passages 64a to 64d, and the passages 63a to 63d form cooling passages 61a to 61d (an example of a first passage) for the electronic units 31a to 31d, respectively. For example, the supply connection passage 62a is connected to the return connection passage 64a via the passage 63a to form the cooling passage 61a corresponding to the electronic unit 31a. Similarly, the supply connection passage 62b is connected to the return connection passage 64b via the passage 63b to form the cooling passage 61b corresponding to the electronic unit 31b. The cooling passages 61a to 61d do not communicate with each other in portions other than both ends (the supply manifold 56 and the return manifold 58).

The flow rate monitoring unit 70 includes the monitoring control passage 72 (an example of a second passage), a flowmeter 74, and a regulating valve 76.

The monitoring control passage 72 makes connection between the supply manifold 56 and the return manifold 58. The monitoring control passage 72 extending from the supply manifold 56 is connected to the return manifold 58 without passing through the bookshelf-type unit 30, in contrast with the supply connection passages 62a to 62d and the return connection passages 64a to 64d. The flow rate of the secondary refrigerant flowing through the monitoring control passage 72 is controlled by a control unit 80 (an example of a cooling control apparatus), as described below.

The flowmeter 74 measures the flow rate of the secondary refrigerant flowing through the monitoring control passage 72. The flowmeter 74 generates a flow rate pulse signal (hereinafter also referred to as a “detection signal”) corresponding to the flow rate of the secondary refrigerant flowing through the monitoring control passage 72.

The regulating valve 76 adjusts the flow rate of the secondary refrigerant flowing through the monitoring control passage 72. The regulating valve 76 may be a manual valve or may be a valve capable of being electronically controlled, such as an electromagnetic valve. The regulating valve 76 may be omitted.

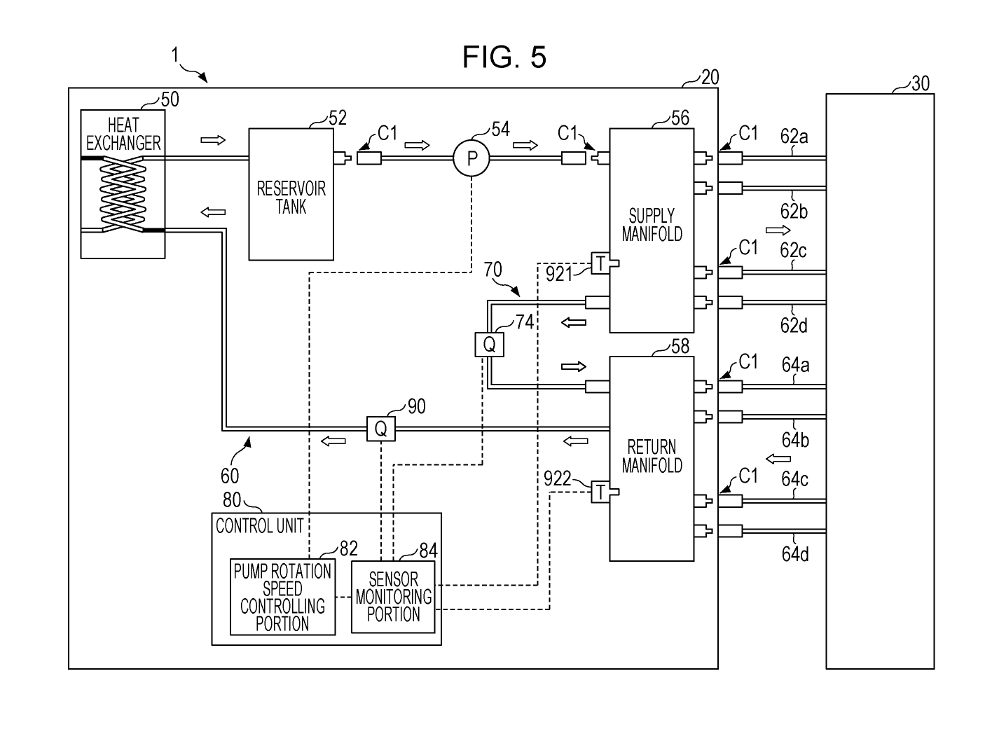

A cooling control system in the electronic apparatus 1 will now be described with reference to FIG. 5 to FIG. 8.

FIG. 5 is an explanatory drawing of the cooling control system in the electronic apparatus 1. Referring to FIG. 5, control lines associated with the control unit 80 are indicated by broken lines. The cooling system described above with reference to FIG. 4 is also illustrated in FIG. 5. The supply connection passages 62a to 62d, the return connection passages 64a to 64d, and both ends of the pump 54 on the water cooling unit passage 60 are indicated to be connected with non-spill couplings C1, such as couplers, in FIG. 5. This enables removal or mounting for maintenance or the like to be easily performed.

The pump 54 to be controlled, the flowmeter 74 in the flow rate monitoring unit 70, and so on are connected to the control unit 80.

The control unit 80 includes a pump rotation speed controlling portion 82 (an example of a pump control unit) and a sensor monitoring portion 84.

The pump rotation speed controlling portion 82 acquires sensor information from the sensor monitoring portion 84. However, the pump rotation speed controlling portion 82 may directly acquire the detection signal from the flowmeter 74. The pump rotation speed controlling portion 82 controls the rotation speed of the pump 54 based on the detection signal from the flowmeter 74. For example, the pump rotation speed controlling portion 82 determines a target rotation speed of the pump 54 and controls the pump 54 so that the rotation speed of the pump 54 is made equal to the target rotation speed while monitoring the rotation speed of the pump 54. Here, the pump rotation speed controlling portion 82 determines the target rotation speed of the pump 54 so that a flow rate Mx (refer to FIG. 4) of the secondary refrigerant flowing through the monitoring control passage 72 is equal to a predetermined flow rate Mref.

The predetermined flow rate Mref is defined in advance (that is, is determined in a design stage) so that the secondary refrigerant is supplied to the cooling passages 61a to 61d corresponding to the electronic units 31a to 31d, respectively, at desired flow rates.

In a state in which the secondary refrigerant is discharged from the pump 54, the flow rate Mx of the secondary refrigerant flowing through the monitoring control passage 72 and flow rates Ma to Md of the secondary refrigerant flowing through the cooling passages 61a to 61d corresponding to the electronic units 31a to 31d, respectively, have predetermined ratios. Specifically, Mx:Ma:Mb:Mc:Md=1: kₐ:k_{b}:k_{c}:k_{d} and kₐ to k_{d} are fixed coefficients. This is because, since the monitoring control passage 72 and the cooling passages 61a to 61d are connected to the common supply manifold 56, as described above, the respective flow rates Mx and Ma to Md are determined based on characteristics of the respective passages. The characteristics of the monitoring control passage 72 and the cooling passages 61a to 61d are the states of the respective passages and typically are pressure loss from the supply manifold 56 to the return manifold 58, the differences in height between the inlets and the outlets, and so on.

In the adjustment of the value of each of the coefficients kₐ to k_{d} in the design stage, an arbitrary adjusting method may be used. For example, the value of each of the coefficients kₐ to k_{d} is capable of being adjusted by adjusting the cross sectional area (diameter) or the length of each of the monitoring control passage 72 and the cooling passages 61a to 61d. In general, the pressure loss is increased and the value of each coefficient is decreased as the cross sectional area of the passage is decreased. In addition, in general, the pressure loss is increased and the value of each coefficient is decreased as the length of the passage is increased. The value of each of the coefficients kₐ to k_{d} is capable of being adjusted by providing an object, such as an orifice ring, a valve, a throttle, or the like in a passage the value of the coefficient of which is to be decreased. When the monitoring control passage 72 includes the regulating valve 76, the characteristics of the monitoring control passage 72 are capable of being adjusted in accordance with the valve opening of the regulating valve 76. The actual value of each of the coefficients kₐ to k_{d} may be confirmed through a test or simulation (numerical calculation). In other words, confirmation and fine tuning of the value of each of the coefficients kₐ to k_{d} may be realized in the design stage through a test or simulation.

Accordingly, the adjustment of the characteristics of each of the monitoring control passage 72 and the cooling passages 61a to 61d in the design stage enables the secondary refrigerant to flow through the respective cooling passages 61a to 61d at desired flow rates when the secondary refrigerant flows through the monitoring control passage 72 at the predetermined flow rate Mref. In other words, the values of the respective coefficients kₐ to k_{d} are determined in accordance with the desired flow rates of the cooling passages 61a to 61d, and the characteristics (for example, the pressure loss) of the monitoring control passage 72 and the cooling passages 61a to 61d are adjusted so as to realize the values of the respective coefficients kₐ to k_{d}. For example, when the desired flow rate of the supply connection passage 62a is denoted by Mta, the coefficient kₐ is kₐ=Mta/Mref. This is because the adjustment of the flow rate Mx of the secondary refrigerant flowing through the monitoring control passage 72 so as to be equal to the predetermined flow rate Mref means adjustment of the flow rate Ma of the secondary refrigerant flowing through the supply connection passage 62a so as to be equal to the desired flow rate Mta. According to the first embodiment, the adjustment of the values of the respective coefficients kₐ to k_{d} in the design stage in the above manner enables the flow rate Mx of the secondary refrigerant flowing through the monitoring control passage 72 to only be adjusted so as to be equal to the predetermined flow rate Mref in service. In other words, in service, the flow rates Ma to Md of the secondary refrigerant flowing through the cooling passages 61a to 61d, respectively, are capable of being controlled so as to be equal to the desired flow rates only by adjusting the flow rate Mx of the secondary refrigerant flowing through the monitoring control passage 72 so as to be equal to the predetermined flow rate Mref.

As a result, according to the first embodiment, since the flow rates of all the cooling passages 61a to 61d are capable of being indirectly detected with the flowmeter 74 on the monitoring control passage 72, the flow rates of the secondary refrigerant flowing through the cooling passages 61a to 61d may not be monitored using flowmeters. Accordingly, the number of the flowmeters is decreased to realize an efficient configuration, for example, compared with a configuration in which the flowmeters are provided for the respective cooling passages 61a to 61d. Such an advantage is made prominent when the electronic apparatus 1 composes the base station apparatus in which the number of the electronic units 31 housed in one bookshelf-type unit 30 is likely to be significantly increased. This is because the flowmeters of a number equal to the number of the electronic units 31 are not provided.

In the electronic apparatus 1 composing the base station apparatus, the number of the electronic units 31 (PIUs) that are provided may be increased or decreased and the apparatus configuration may often be varied depending on the location where the apparatus is mounted. In addition, in the electronic apparatus 1 composing the base station apparatus, since online maintenance of the electronic units 31 is desired and stopping of the service is disabled, exchange or maintenance of the electronic units 31 is performed while the service is kept continued.

For example, a configuration in a comparative example in which a flowmeter is provided between the pump 54 and the supply manifold 56 and the discharge rate of the pump 54 is controlled so as to be equal to a predetermined value based on a detection signal of the flowmeter has the following disadvantage. Specifically, when the number of the electronic units 31 is increased or is decreased for maintenance or the like, the discharge rate of the pump 54 is kept at the predetermined value and is not varied before and after the increase or decrease in the number of the electronic units 31. Accordingly, the flow rate of the secondary refrigerant flowing through the cooling passage corresponding to each electronic unit 31 in use is varied.

In contrast, according to the first embodiment, the disadvantage occurring in the comparative example is capable of being suppressed. Specifically, according to the first embodiment, the flow rate Mx of the secondary refrigerant flowing through the monitoring control passage 72 is controlled so as to be equal to the predetermined flow rate Mref, as described above. Accordingly, when the number of the electronic units 31 is increased or is decreased for maintenance or the like, the flow rate Mx of the secondary refrigerant flowing through the monitoring control passage 72 is kept at the predetermined flow rate Mref before and after the increase or decrease in the number of the electronic units 31 according to the first embodiment. This means that the flow rates Ma to Md of the secondary refrigerant flowing through the cooling passages 61a to 61d, respectively, are also kept at the desired flow rates. For example, even if the electronic unit 31a is removed for maintenance and inspection, the flow rate Mx of the secondary refrigerant flowing through the monitoring control passage 72 is kept at the predetermined flow rate Mref and, thus, the flow rates Mb to Md of the secondary refrigerant flowing through the cooling passages 61b to 61d, respectively, are also kept at the desired flow rates. As described above, according to the first embodiment, even when the configuration of the electronic units 31 housed in the bookshelf-type unit 30 is varied due to the increase or decrease of the electronic units 31 that are provided, the online maintenance, or the like, the secondary refrigerant is stably supplied to the respective electronic units 31 at the desired flow rates.

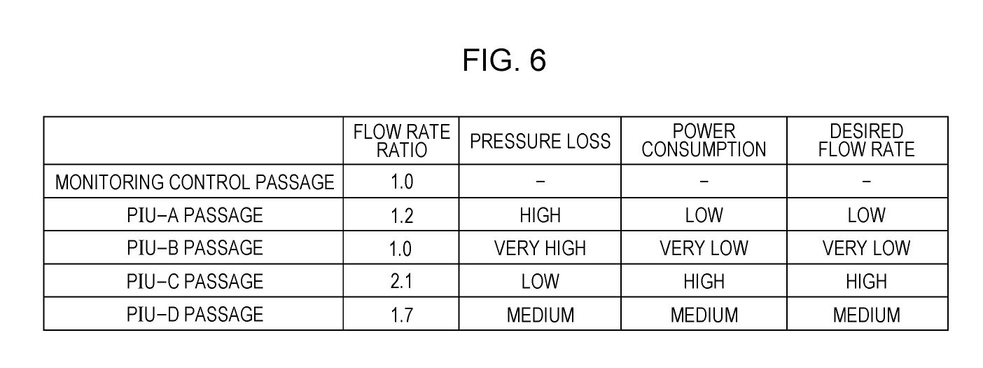

FIG. 6 is a table illustrating an example of the relationship between flow rate ratios and power consumption. Referring to FIG. 6, a PIU-A passage corresponds to the cooling passage 61a corresponding to the electronic unit 31a and a PIU-B passage corresponds to the cooling passage 61b corresponding to the electronic unit 31b. The same applies to the other passages. The flow rate ratios correspond to the values of the respective coefficients kₐ to k_{d}.

In the first row in the table in FIG. 6, “POWER CONSUMPTION” corresponds to the power consumption in the electronic units 31a to 31d and may be a value that is actually measured or a rated value. For example, the power consumption of the electronic unit 31a may be the power consumption of the entire electronic unit 31a or may be the power consumption of part of the electronic unit 31a (for example, the power consumption of a device to be cooled with the cooling passage 61a). Relative magnitudes of the power consumption are indicated in the table in FIG. 6 as an example. In the example in FIG. 6, the power consumption of the electronic unit 31a is “LOW”, the power consumption of the electronic unit 31b is “VERY LOW”, the power consumption of the electronic unit 31c is “HIGH”, and the power consumption of the electronic unit 31d is “MEDIUM”. In this case, the desired flow rates for the flow rates Ma to Md of the secondary refrigerant flowing through the cooling passages 61a to 61d, respectively, desirably have relative relationship corresponding to the relative relationship of the power consumptions between the electronic units 31a to 31d. Specifically, the desired flow rates for the flow rates Ma to Md of the secondary refrigerant flowing through the cooling passages 61a to 61d, respectively, are sequentially “LOW”, “VERY LOW”, “HIGH”, and “MEDIUM”, as illustrated in FIG. 6. The values of the respective coefficients kₐ to k_{d} to realize the relative relationship of the desired flow rates are, for example, “1.2”, “1.0”, “2.1”, and “1.7”, as illustrated in FIG. 6. The relative relationship of the pressure loss to realize the values of the respective coefficients kₐ to k_{d} is sequentially “HIGH”, “VERY HIGH”, “LOW”, and “MEDIUM”. Accordingly, in this case, the adjustment of the values of the respective coefficients kₐ to k_{d} to “1.2”, “1.0”, “2.1”, and “1.7” in the design stage enables the flow rates Ma to Md of the secondary refrigerant flowing through the cooling passages 61a to 61d, respectively, to be controlled so as to be equal to the desired flow rates, as described above.

Since the desired flow rates for the flow rates Ma to Md of the secondary refrigerant flowing through the cooling passages 61a to 61d, respectively, are determined in accordance with the relative relationship of the power consumption between the electronic units 31a to 31d in the above manner in the example illustrated in FIG. 6, efficient cooling is realized. In other words, supply of the flow rate that is too high to the cooling passage corresponding to the electronic unit 31 having relatively low power consumption or shortage of the flow rate supplied to the cooling passage corresponding to the electronic unit 31 having relatively high power consumption is suppressed to realize the efficient cooling.

In the example illustrated in FIG. 5, a flowmeter 90 and water temperature meters 921 and 922 are further connected to the control unit 80. The flowmeter 90 measures the entire flow rate of the water cooling unit passage 60. The water temperature meter 921 measures the temperature of the secondary refrigerant in the supply manifold 56, and the water temperature meter 922 measures the temperature of the secondary refrigerant in the return manifold 58.

The sensor monitoring portion 84 monitors the state of the cooling system (for example, presence of an abnormal condition) based on the detection signals from the flowmeter 90 and the water temperature meters 921 and 922.

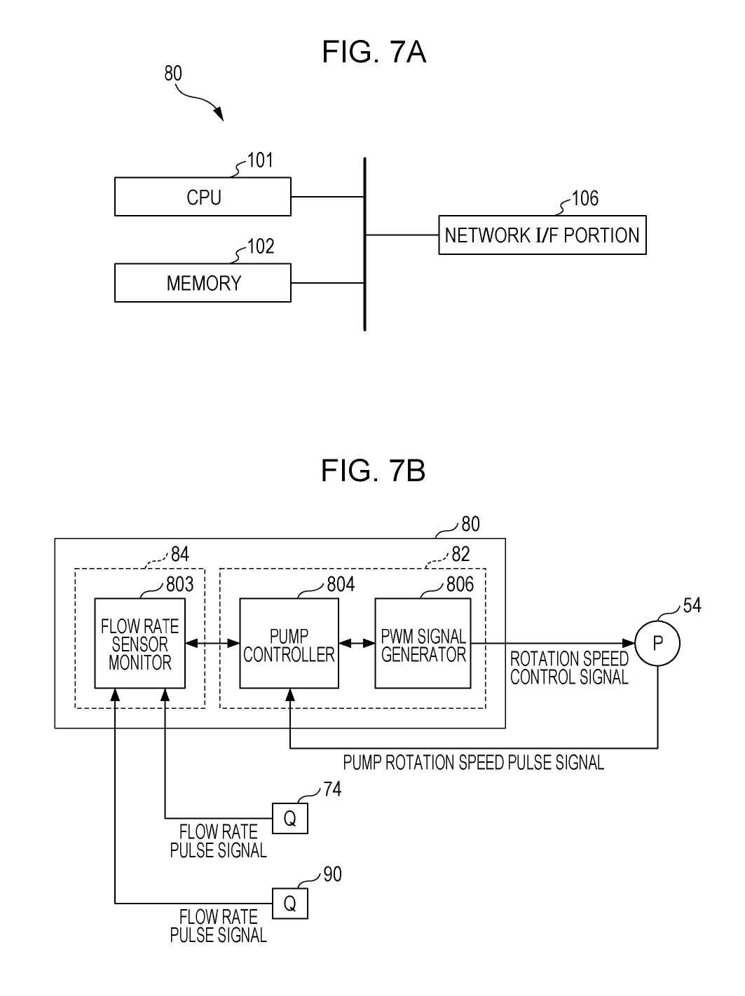

FIG. 7A illustrates an exemplary hardware configuration of the control unit 80.

In the example illustrated in FIG. 7A, the control unit 80 includes a central processing unit (CPU) 101, a memory 102, and a network interface (I/F) portion 106. The network I/F portion 106 is an interface between the control unit 80 and a peripheral device that is connected over a network built with data transmission paths, such as wired and/or wireless lines, and that has a communication function.

FIG. 7B schematically illustrates an exemplary functional configuration of the control unit 80. The pump 54 and so on are illustrated in FIG. 7B, with the schematic functional configuration of the control unit 80.

The control unit 80 includes a flow rate sensor monitor 803, a pump controller 804, and a pulse width modulation (PWM) signal generator 806. The flow rate sensor monitor 803, the pump controller 804, and the PWM signal generator 806 are realized by the CPU 101 illustrated in FIG. 7A which executes a program in the memory 102. The pump controller 804 and the PWM signal generator 806 are included in the pump rotation speed controlling portion 82 and the flow rate sensor monitor 803 is included in the sensor monitoring portion 84.

The flow rate sensor monitor 803 receives the detection signals (the flow rate pulse signals) from the flowmeter 74 and the flowmeter 90.

The pump controller 804 receives an electrical signal (a pump rotation speed pulse signal) corresponding to the rotation speed of the pump 54 from a rotation speed sensor (not illustrated) in the pump 54. In addition, the pump controller 804 supplies a signal corresponding to the target rotation speed to the PWM signal generator 806 to cause the PWM signal generator 806 to generate a PWM signal of a duty corresponding to the target rotation speed. The PWM signal is supplied to the pump 54 as a rotation speed control signal. The pump 54 is driven in response to the rotation speed control signal.

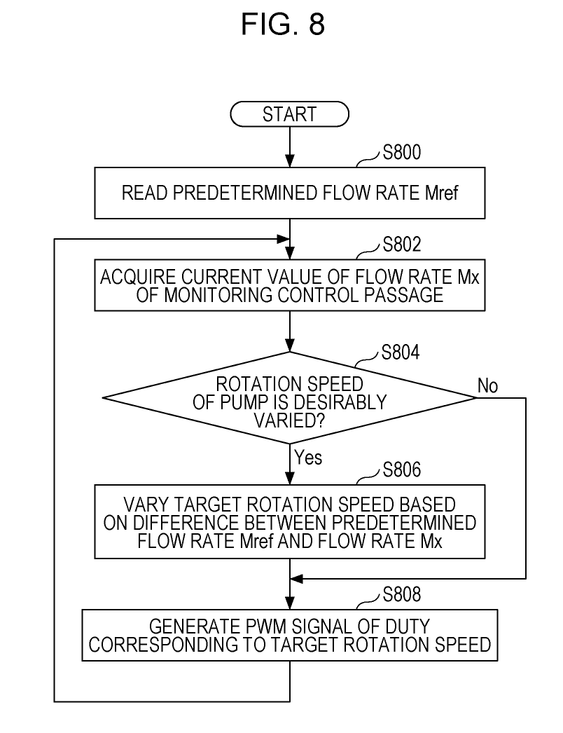

FIG. 8 is a flowchart schematically illustrating an exemplary process realized by the pump rotation speed controlling portion 82. The process illustrated in FIG. 8 is performed on a predetermined control cycle.

Referring to FIG. 8, in Step S800, the pump rotation speed controlling portion 82 reads out the predetermined flow rate Mref from the memory 102.

In Step S802, the pump rotation speed controlling portion 82 acquires the current value of the flow rate Mx of the monitoring control passage 72 based on the detection signal from the flowmeter 74.

In Step S804, the pump rotation speed controlling portion 82 compares the predetermined flow rate Mref with the current value of the flow rate Mx to determine whether the rotation speed of the pump 54 is desirably varied. For example, the pump rotation speed controlling portion 82 determines that the rotation speed of the pump 54 is desirably varied if the difference between the predetermined flow rate Mref and the current value of the flow rate Mx is greater than or equal to a predetermined value. The process goes to Step S806 if the determination result in Step S804 is YES and otherwise goes to Step S808.

In Step S806, the pump rotation speed controlling portion 82 varies the target rotation speed of the pump 54 based on the difference between the predetermined flow rate Mref and the current value of the flow rate Mx.

In Step S808, the pump rotation speed controlling portion 82 generates the PWM signal of a duty corresponding to the target rotation speed to control the rotation speed of the pump 54 so as to realize the target rotation speed.

Using the process illustrated in FIG. 8, the flow rate Mx in the monitoring control passage 72 is capable of being controlled so as to be equal to the predetermined flow rate Mref based on information about the flow rate Mx in the monitoring control passage 72, acquired from the flowmeter 74, while the cooling system is in use. Accordingly, even if the flow rate Mx in the monitoring control passage 72 is significantly deviated from the predetermined flow rate Mref, the flow rate Mx in the monitoring control passage 72 is capable of being kept at the predetermined flow rate Mref by varying the rotation speed of the pump 54.

The process in FIG. 8 is only an example and various methods may be used to control the pump 54 so as to realize the predetermined flow rate Mref. For example, Step S804 may be omitted and feedback control may be realized with no condition.

Although the flow rate monitoring unit 70 includes the flowmeter 74 in the first embodiment described above (the same applies to second and fifth embodiments described below), a pressure sensor that measures the pressure of the secondary refrigerant in the monitoring control passage 72 may be provided, instead of the flowmeter 74. This is because the pressure of the secondary refrigerant in the monitoring control passage 72 correlates with the flow rate of the secondary refrigerant in the monitoring control passage 72.

Although one predetermined flow rate Mref is used in the first embodiment described above (the same applies to second to fifth embodiments described below), two or more predetermined flow rates Mref may differently be used. Although the power consumption of the pump 54 is increased as the predetermined flow rate Mref is increased, the cooling capacity is improved. Accordingly, for example, when the predetermined flow rate Mref has a first predetermined flow rate Mref and a second predetermined flow rate Mref greater than the first predetermined flow rate Mref, the second predetermined flow rate Mref may be used if the processing load on the electronic unit 31 in the electronic apparatus 1 is relatively high. Alternatively, since the amount of heat transfer to the secondary refrigerant is increased if the temperature of the secondary refrigerant is relatively low based on the results of detection in the water temperature meters 921 and 922, the second predetermined flow rate Mref may be used. In this case, priority is given to the cooling performance and the device temperature in the electronic unit 31 is sufficiently decreased. Alternatively, since the cooling is sufficiently realized with a low flow rate if the temperature of the secondary refrigerant is relatively low, the first predetermined flow rate Mref (or a flow rate lower than the first predetermined flow rate Mref) may be used. In this case, the power consumption of the pump 54 and the load on the pump 54 are capable of being reduced while keeping the device temperature in the electronic unit 31 within an allowable range.

### Second Embodiment

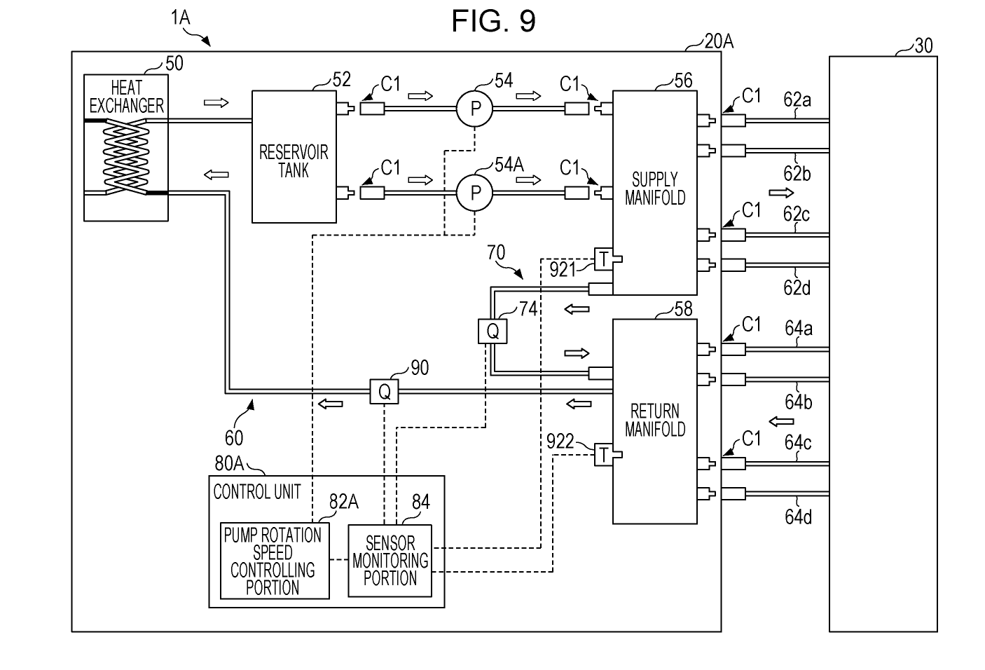

A cooling control system in an electronic apparatus 1A according to a second embodiment will now be described with reference to FIG. 9.

The electronic apparatus 1A according to the second embodiment differs from the electronic apparatus 1 according to the first embodiment in that the water cooling unit 20 is replaced with a water cooling unit 20A and the control unit 80 is replaced with a control unit 80A.

FIG. 9 is an explanatory drawing of the cooling control system in the electronic apparatus 1A. Referring to FIG. 9, control lines associated with the control unit 80A are indicated by broken lines. The same reference numerals are used in FIG. 9 to identify the same components as those in the electronic apparatus 1 according to the first embodiment. A description of such components is omitted herein.

The water cooling unit 20A according to the second embodiment differs from the water cooling unit 20 according to the first embodiment in that a pump 54A is added, in addition to the pump 54.

The pump 54A is provided in parallel with the pump 54. Specifically, the pump 54A is provided between the reservoir tank 52 and the supply manifold 56. Accordingly, in the second embodiment, the secondary refrigerant is capable of being supplied from the reservoir tank 52 to the supply manifold 56 with the two pumps 54 and 54A.

The control unit 80A according to the second embodiment differs from the control unit 80 according to the first embodiment in that the pump rotation speed controlling portion 82 is replaced with a pump rotation speed controlling portion 82A (an example of the pump control unit).

The pump rotation speed controlling portion 82A controls the rotation speeds of the pumps 54 and 54A based on the detection signal from the flowmeter 74. For example, the pump rotation speed controlling portion 82A determines the target rotation speeds of the pumps 54 and 54A and controls the pumps 54 and 54A so that the rotation speeds of the pumps 54 and 54A are made equal to the respective target rotation speeds while monitoring the rotation speeds of the pumps 54 and 54A. Here, the pump rotation speed controlling portion 82A determines the target rotation speeds of the pumps 54 and 54A so that the flow rate Mx (refer to FIG. 4) of the secondary refrigerant flowing through the monitoring control passage 72 is equal to the predetermined flow rate Mref.

According to the second embodiment, the advantages similar to those in the first embodiment are achieved. In addition, according to the second embodiment, since the two pumps 54 and 54A are provided, the cooling function is capable of being automatically kept with one pump even if the other pump fails. Also in a maintenance operation, such as exchange of the pump, the cooling function is also capable of being automatically kept with one pump if the other pump is removed. For example, setting the duties of the PWM signals supplied to the pumps 54 and 54A to, for example, values that do not exceed 50% in normal times enables the duty of the PWM signal supplied to one pump to be increased, for example, if the other pump fails. Accordingly, increasing the duty of the PWM signal supplied to one pump, for example, if the other pump fails enables the flow rate Mx of the secondary refrigerant flowing through the monitoring control passage 72 to be kept at the predetermined flow rate Mref. However, when the flow rate Mx of the secondary refrigerant flowing through the monitoring control passage 72 is not set to the predetermined flow rate Mref with only one pump due to the capacities of the pumps 54 and 54A, the discharge rate of the other pump may be set to a maximum value only during the failure or the like. Also in this case, the cooling function is improved, compared with the case in which only one pump is used, although the cooling capacity is slightly reduced.

Although the two pumps 54 and 54A are used in the second embodiment, three or more pumps may be used.

### Third Embodiment

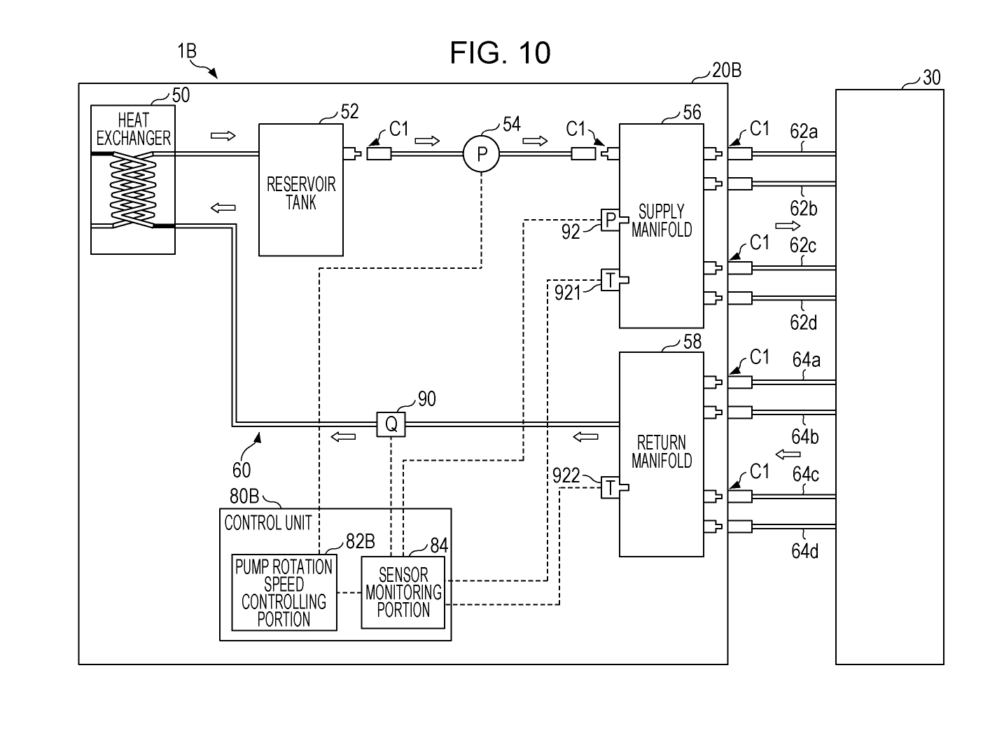

A cooling control system in an electronic apparatus 1B according to a third embodiment will now be described with reference to FIG. 10.

The electronic apparatus 1B according to the third embodiment differs from the electronic apparatus 1 according to the first embodiment in that the water cooling unit 20 is replaced with a water cooling unit 20B and the control unit 80 is replaced with a control unit 80B.

FIG. 10 is an explanatory drawing of the cooling control system in the electronic apparatus 1B. Referring to FIG. 10, control lines associated with the control unit 80B are indicated by broken lines. The same reference numerals are used in FIG. 10 to identify the same components as those in the electronic apparatus 1 according to the first embodiment. A description of such components is omitted herein.

The water cooling unit 20B according to the third embodiment differs from the water cooling unit 20 according to the first embodiment in that the flow rate monitoring unit 70 is omitted and a pressure sensor 92 is added.

The pressure sensor 92 measures the pressure of the secondary refrigerant in the supply manifold 56. The pressure sensor 92 may be provided in the supply manifold 56 or may be provided at a portion where a pressure similar to the pressure of the secondary refrigerant in the supply manifold 56 is capable of being measured.

The control unit 80B according to the third embodiment differs from the control unit 80 according to the first embodiment in that the pump rotation speed controlling portion 82 is replaced with a pump rotation speed controlling portion 82B (an example of the pump control unit).

The pump rotation speed controlling portion 82B controls the rotation speed of the pump 54 based on the detection signal from the pressure sensor 92. For example, the pump rotation speed controlling portion 82B determines the target rotation speed of the pump 54 and controls the pump 54 so that the rotation speed of the pump 54 is made equal to the target rotation speed while monitoring the rotation speed of the pump 54. Here, the pump rotation speed controlling portion 82B determines the target rotation speed of the pump 54 so that a pressure Px of the secondary refrigerant in the supply manifold 56 is equal to a predetermined pressure Pref.

The predetermined pressure Pref is defined in advance so that the secondary refrigerant is supplied to the cooling passages 61a to 61d corresponding to the electronic units 31a to 31d, respectively, at desired flow rates.

Here, the flow velocity of the secondary refrigerant in the supply manifold 56 is low and the kinetic energy thereof is negligibly small. Accordingly, the pressure Px of the secondary refrigerant in the supply manifold 56 is substantially the same at any portion in the supply manifold 56 and is the same at the inlets of the cooling passages 61a to 61d. This means that the flow rates Ma to Md of the secondary refrigerant flowing through the cooling passages 61a to 61d corresponding to the electronic units 31a to 31d, respectively, are determined based on the pressure Px of the secondary refrigerant in the supply manifold 56 and the characteristics of the respective passages. In other words, the pressure Px of the secondary refrigerant in the supply manifold 56 is a parameter indicating the flow rates of the secondary refrigerant flowing through the cooling passages 61a to 61d.

Accordingly, in the state in which the secondary refrigerant is discharged from the pump 54, the pressure Px of the secondary refrigerant in the supply manifold 56 and the flow rates Ma to Md of the secondary refrigerant flowing through the cooling passages 61a to 61d corresponding to the electronic units 31a to 31d, respectively, have predetermined ratios. Specifically, Px:Ma:Mb:Mc:Md=1:mₐ:m_{b}:m_{c}:m_{d} and mₐ to m_{d} are fixed coefficients. The value of each of the coefficients mₐ to m_{d} is capable of being adjusted in the design stage, like each of the coefficients kₐ to k_{d}. The value of each of the coefficients mₐ to m_{d} is capable of being adjusted in the design stage using the same method as that of adjusting the value of each of the coefficients kₐ to k_{d} described above.

According to the third embodiment, the advantages similar to those in the first embodiment are achieved. In addition, according to the third embodiment, since the use of the pressure sensor 92, instead of the flow rate monitoring unit 70, achieves the advantages similar to those in the first embodiment, a simple configuration is realized.

### Fourth Embodiment

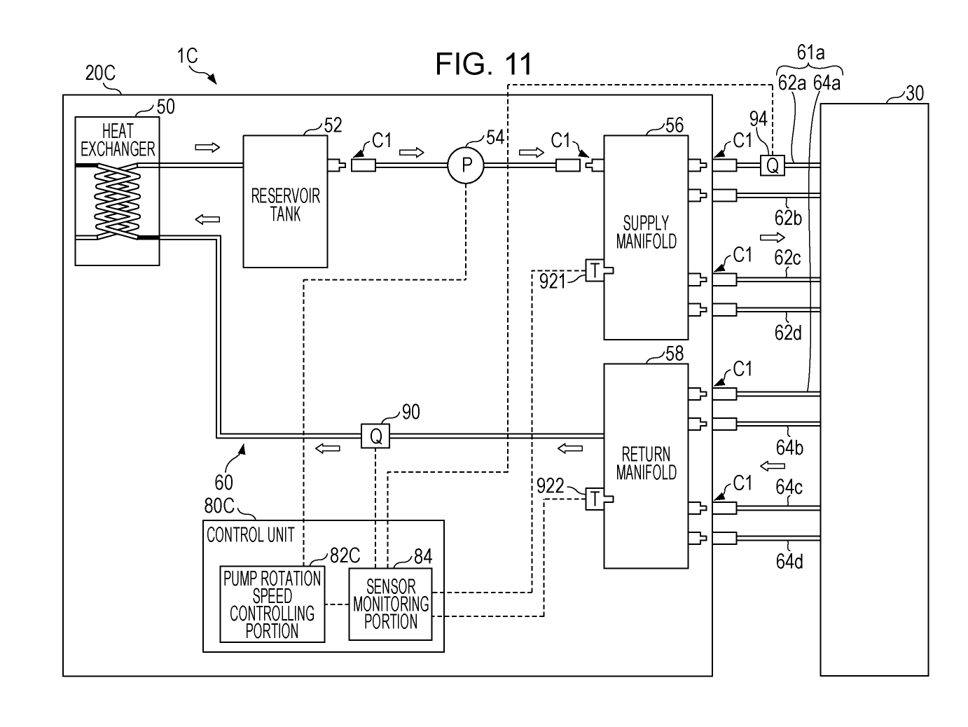

A cooling control system in an electronic apparatus 1C according to a fourth embodiment will now be described with reference to FIG. 11.

The electronic apparatus 1C according to the fourth embodiment differs from the electronic apparatus 1 according to the first embodiment in that the water cooling unit 20 is replaced with a water cooling unit 20C and the control unit 80 is replaced with a control unit 80C.

FIG. 11 is an explanatory drawing of the cooling control system in the electronic apparatus 1C. Referring to FIG. 11, control lines associated with the control unit 80C are indicated by broken lines. The same reference numerals are used in FIG. 11 to identify the same components as those in the electronic apparatus 1 according to the first embodiment. A description of such components is omitted herein.

The water cooling unit 20C according to the fourth embodiment differs from the water cooling unit 20 according to the first embodiment in that the flow rate monitoring unit 70 is omitted and a flowmeter 94 is added.

The flowmeter 94 is provided on the cooling passage 61a, among the cooling passages 61a to 61d corresponding to the electronic units 31a to 31d, respectively. However, the flowmeter 94 may be provided on one of the cooling passages 61b to 61d, instead of the cooling passage 61a. The flowmeter 94 is desirably provided on the cooling passage corresponding to the electronic unit 31 most likely to be installed, among the electronic units 31a to 31d. In other words, the flowmeter 94 is desirably provided on the cooling passage corresponding to the electronic unit 31 that is installed if the apparatus configuration is varied.

The control unit 80C according to the fourth embodiment differs from the control unit 80 according to the first embodiment in that the pump rotation speed controlling portion 82 is replaced with a pump rotation speed controlling portion 82C (an example of the pump control unit).

The pump rotation speed controlling portion 82C controls the rotation speed of the pump 54 based on the detection signal from the flowmeter 94. For example, the pump rotation speed controlling portion 82C determines the target rotation speed of the pump 54 and controls the pump 54 so that the rotation speed of the pump 54 is made equal to the target rotation speed while monitoring the rotation speed of the pump 54. Here, the pump rotation speed controlling portion 82C determines the target rotation speed of the pump 54 so that the flow rate Ma of the secondary refrigerant flowing through the cooling passage 61a is equal to a predetermined flow rate Maref.

The predetermined flow rate Maref is defined in advance so that the secondary refrigerant is supplied to the cooling passages 61a to 61d corresponding to the electronic units 31a to 31d, respectively, at desired flow rates.

In the state in which the secondary refrigerant is discharged from the pump 54, the flow rates Ma to Md of the secondary refrigerant flowing through the cooling passages 61a to 61d corresponding to the electronic units 31a to 31d, respectively, have predetermined ratios. Specifically, Ma:Mb:Mc:Md=kₐ:k_{b}:k_{c}:k_{d} and kₐ to k_{d} are fixed coefficients. This is because, since the cooling passages 61a to 61d are connected to the common supply manifold 56, as described above, the respective flow rates Ma to Md are determined based on characteristics of the respective passages. In the case of the fourth embodiment, since the flow rate Ma of the secondary refrigerant flowing through the cooling passage 61a is controlled so as to be equal to the predetermined flow rate Maref, the flow rates Mb to Md of the secondary refrigerant flowing through the cooling passages 61b to 61d, respectively, are determined by the values of the coefficients kₐ to k_{d}. The value of each of the coefficients kₐ to k_{d} is capable of being adjusted in the design stage, as in the first embodiment described above.

According to the fourth embodiment, the advantages similar to those in the first embodiment are achieved. In addition, according to the fourth embodiment, since the cooling passage 61a is used, instead of the monitoring control passage 72, a simple configuration is realized.

### Fifth Embodiment

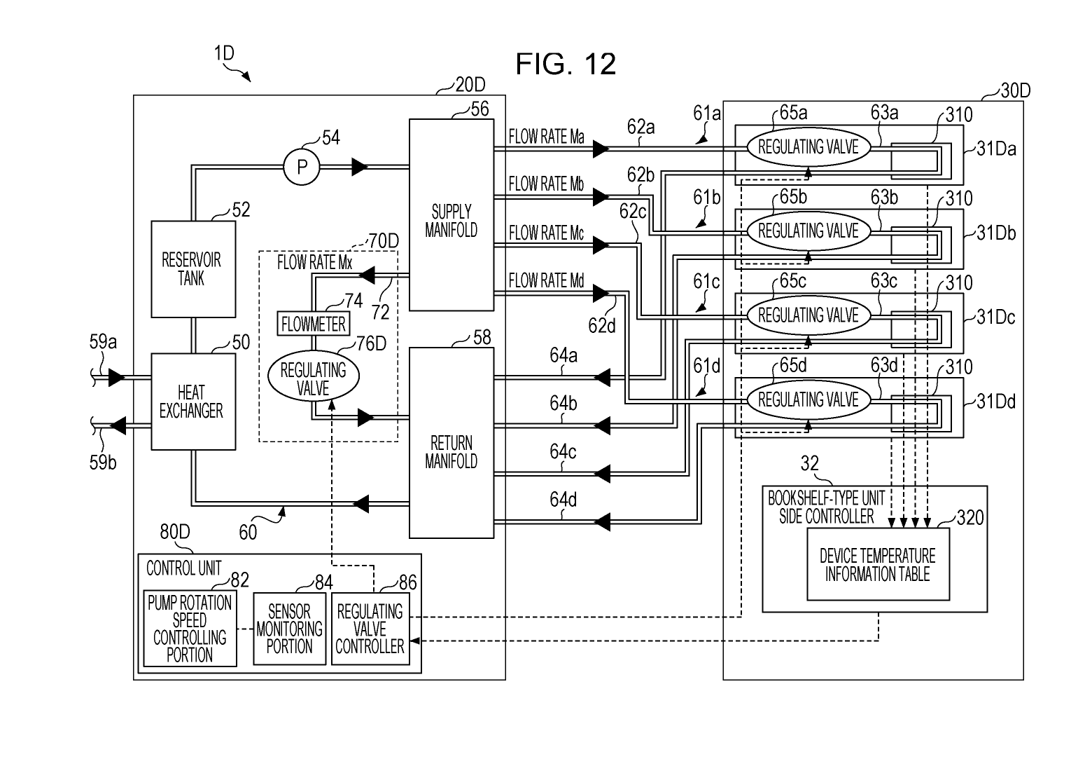

A cooling control system in an electronic apparatus 1D according to a fifth embodiment will now be described with reference to FIG. 12 to FIG. 16.

The electronic apparatus 1D according to the fifth embodiment differs from the electronic apparatus 1 according to the first embodiment in that the water cooling unit 20 and the bookshelf-type unit 30 are replaced with a water cooling unit 20D and a bookshelf-type unit 30D and the control unit 80 is replaced with a control unit 80D.

FIG. 12 is an explanatory drawing of the cooling control system in the electronic apparatus 1D. Referring to FIG. 12, control lines associated with the control unit 80D are indicated by broken lines. The same reference numerals are used in FIG. 12 to identify the same components as those in the electronic apparatus 1 according to the first embodiment. A description of such components is omitted herein. A bookshelf-type unit side controller 32 is illustrated as a controller in the bookshelf-type unit 30D.

The water cooling unit 20D according to the fifth embodiment differs from the water cooling unit 20 according to the first embodiment in that the flow rate monitoring unit 70 is replaced with a flow rate monitoring unit 70D. The flow rate monitoring unit 70D according to the fifth embodiment differs from the flow rate monitoring unit 70 according to the first embodiment in that the regulating valve 76 is replaced with a regulating valve 76D. The regulating valve 76D differs from the regulating valve 76 according to the first embodiment, which may not be an electromagnetic valve, in that the regulating valve 76D is a valve the valve opening of which is capable of electronically controlled and is, for example, a proportional electromagnetic valve.

The bookshelf-type unit 30D according to the fifth embodiment differs from the bookshelf-type unit 30 according to the first embodiment in that the electronic units 31 (the electronic units 31a to 31d) are replaced with electronic units 31D (electronic units 31Da to 31Dd).

The electronic units 31Da to 31Dd differ from the electronic units 31a to 31d according to the first embodiment in that the electronic units 31Da to 31Dd include regulating valves 65a to 65d (an example of a flow rate regulating valve) on the passages 63a to 63d, respectively. The regulating valves 65a to 65d are devices for adjusting the flow rates of the secondary refrigerant flowing through the passages 63a to 63d, respectively. The regulating valves 65a to 65d are valves the valve openings of which are capable of being electronically controlled and are, for example, proportional electromagnetic valves. The regulating valves 65a to 65d may be provided on the supply connection passages 62a to 62d or may be provided on the return connection passages 64a to 64d.

The control unit 80D according to the fifth embodiment differs from the control unit 80 according to the first embodiment in that a regulating valve controller 86 is added. The hardware configuration of the control unit 80D may be the same as that of the control unit 80 according to the first embodiment. The regulating valve controller 86 is capable of being realized by, for example, the CPU 101 that executes a program in the memory 102.

The regulating valve controller 86 controls the valve openings of the regulating valve 76D and the regulating valves 65a to 65d in response to an instruction from the bookshelf-type unit side controller 32, as described below.

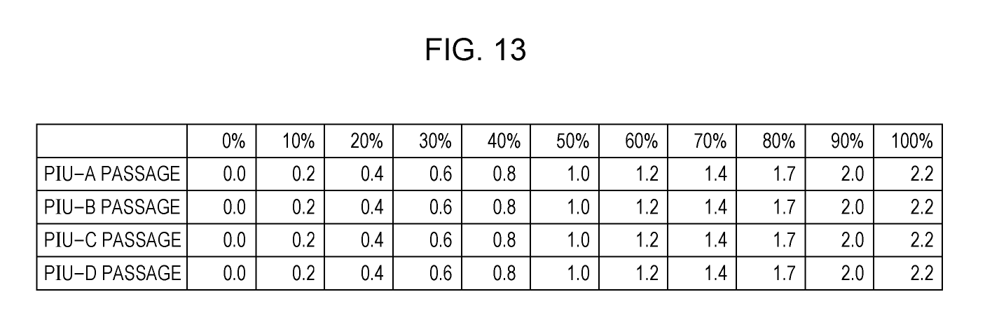

FIG. 13 is a table illustrating an example of the relationship between the valve openings of the regulating valves 65a to 65d and the flow rate ratios. Referring to FIG. 13, percentage values in the first row indicate the valve openings of the regulating valves 65a to 65d. In addition, referring to FIG. 13, a PIU-A passage corresponds to the cooling passage 61a corresponding to the electronic unit 31Da and a PIU-B passage corresponds to the cooling passage 61b corresponding to the electronic unit 31Db. The same applies to the remaining passages. Referring to FIG. 13, the figures in the table indicate the ratios of the flow rates Ma to Md of the secondary refrigerant flowing through the cooling passages 61a to 61d, respectively, when the valve openings of the regulating valves 65a to 65d have the percent values indicated in the first row. The ratios are based on the flow rate Mx of the secondary refrigerant flowing through the monitoring control passage 72, which is set to “1”. For example, when the valve openings of the regulating valves 65a to 65d are 30%, all the flow rate ratios of the secondary refrigerant flowing through the cooling passages 61a to 61d are “0.6”. The numerical value of each ratio in FIG. 13 is calculated in advance through, a test or the like. The numerical values illustrated in FIG. 13 are only for description and the ratios of the flow rates Ma to Md of the secondary refrigerant flowing through the cooling passages 61a to 61d, respectively, may practically be different values even if the regulating valves 65a to 65d have the same valve opening.

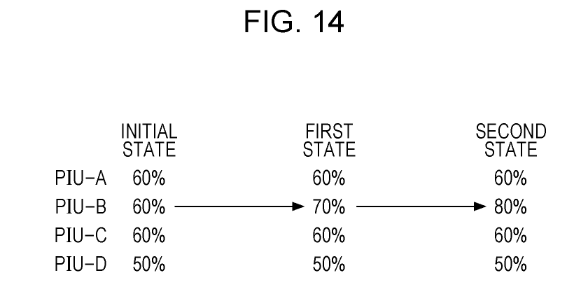

FIG. 14 is a diagram illustrating an image of the content of control by the regulating valve controller 86.

In an initial state, the regulating valve controller 86 sets the valve openings of the regulating valves 65a to 65d to default values, for example, to 60%, 60%, 60%, and 50%. Referring to FIG. 14, the initial state makes transition to a first state when the temperature of the electronic unit 31Db (PIU-B) is increased to a value higher than an allowable temperature range. In the first state, the regulating valve controller 86 increases only the valve opening of the regulating valve 65b, among the regulating valves 65a to 65d, to 70%. As apparent from FIG. 13, this increases the flow rate ratio of the secondary refrigerant flowing through the cooling passage 61b from “1.2” to “1.4” to improve the cooling capacity for the electronic unit 31Db. Referring to FIG. 14, the first state makes transition to a second state in response to the temperature of the electronic unit 31Db (PIU-B), which is still higher than the allowable temperature rage. In the second state, the regulating valve controller 86 increases only the valve opening of the regulating valve 65b to 80%. As apparent from FIG. 13, this increases the flow rate ratio of the secondary refrigerant flowing through the cooling passage 61b from “1.4” to “1.7” to improve the cooling capacity for the electronic unit 31Db.

As described above, according to the fifth embodiment, the efficient cooling associated with the device temperatures in the electronic units 31Da to 31Dd is capable of being realized.

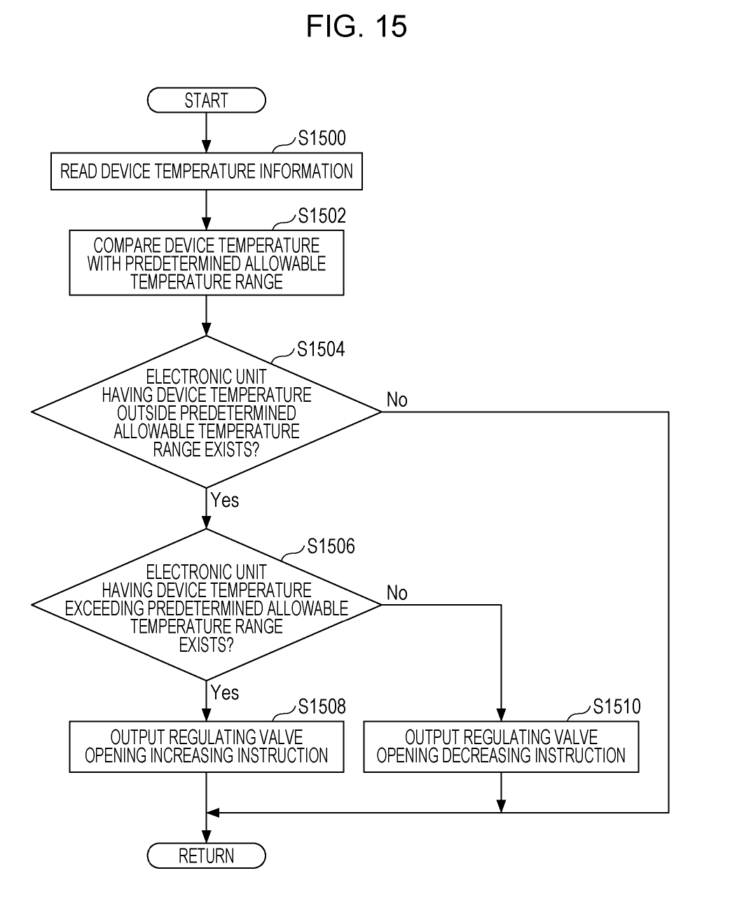

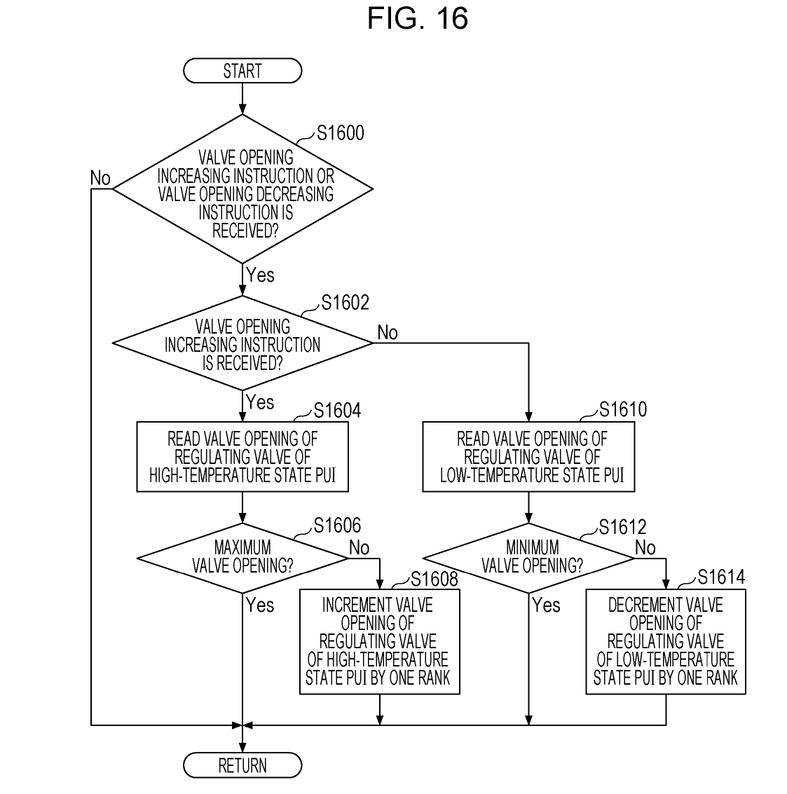

Specific exemplary operations in the electronic apparatus 1D according to the fifth embodiment will now be described with reference to FIG. 15 and FIG. 16.

FIG. 15 is a flowchart illustrating an exemplary process performed by the bookshelf-type unit side controller 32. The process illustrated in FIG. 15 may be repeatedly performed on a predetermined monitoring cycle.

Referring to FIG. 15, in Step S1500, the bookshelf-type unit side controller 32 refers to a device temperature information table 320 to read out device temperature information (current value) about each electronic unit 31D in the bookshelf-type unit 30D. Latest data on the device temperature information about each electronic unit 31D is stored in the device temperature information table 320.

In Step S1502, the bookshelf-type unit side controller 32 compares the device temperature of each electronic unit 31D with a predetermined allowable temperature range. The predetermined allowable temperature range may be set for each electronic unit 31D.

In Step S1504, the bookshelf-type unit side controller 32 determines whether the electronic unit 31D having a device temperature outside the predetermined allowable temperature range exists. The process goes to Step S1506 if the determination result is YES and, otherwise (that is, if all the electronic units 31D have device temperatures within the predetermined allowable temperature range), the process on the current cycle is terminated.

In Step S1506, the bookshelf-type unit side controller 32 determines whether the electronic unit 31D having a device temperature exceeding the predetermined allowable temperature range (that is, an upper limit of the allowable temperature range) exists. The process goes to Step S1508 if the determination result is YES and, otherwise (that is, if no electronic unit 31D has a device temperature exceeding the predetermined allowable temperature range), the process goes to Step S1510.

In Step S1508, the bookshelf-type unit side controller 32 issues a regulating valve opening increasing instruction for the electronic unit 31D having the device temperature exceeding the predetermined allowable temperature range (hereinafter referred to as the electronic unit 31D in a high-temperature state) to the control unit 80D.

In Step S1510, the bookshelf-type unit side controller 32 issues a regulating valve opening decreasing instruction for the electronic unit 31D having the device temperature lower than the predetermined allowable temperature range (that is, a lower limit of the allowable temperature range) (hereinafter referred to as the electronic unit 31D in a low-temperature state) to the control unit 80D.

FIG. 16 is a flowchart illustrating an exemplary process performed by the regulating valve controller 86 in the control unit 80D. The process illustrated in FIG. 16 may be performed on, for example, a cycle synchronized with the process illustrated in FIG. 15. Also in the fifth embodiment, the pump rotation speed controlling portion 82 in the control unit 80D controls the rotation speed of the pump 54 in the same aspect as that in the first embodiment (for example, refer to FIG. 8).

Referring to FIG. 16, in Step S1600, the regulating valve controller 86 determines whether the valve opening increasing instruction or the valve opening decreasing instruction is received from the bookshelf-type unit side controller 32. The process goes to Step S1602 if the determination result is YES and, otherwise (that is, none of the valve opening increasing instruction and the valve opening decreasing instruction is received), the process on the current cycle is terminated.

In Step S1602, the regulating valve controller 86 determines whether the valve opening increasing instruction is received. The process goes to Step S1604 if the determination result is YES and, otherwise (that is, the valve opening decreasing instruction is received), the process goes to Step S1610.

In Step S1604, the regulating valve controller 86 reads out the current valve opening of the regulating valve corresponding to the electronic unit 31D in the high-temperature state for which the valve opening increasing instruction is issued, among the regulating valves 65a to 65d, in response to reception of the valve opening increasing instruction. The current valve openings of the regulating valves 65a to 65d may be held as a valve opening information table (not illustrated).

In Step S1606, the regulating valve controller 86 determines whether the current valve opening of the regulating valve, acquired in Step S1604, is equal to a maximum valve opening (that is, 100%). If the determination result is YES, the process on the current cycle is terminated because the valve opening is not further increased. However, in a modification, if the determination result in Step S1606 is YES, the regulating valve controller 86 may decrement the valve opening of each of the regulating valves corresponding to the electronic units 31D other than the electronic unit 31D in the high-temperature state, among the regulating valves 65a to 65d, and the regulating valve 76D by one rank. Alternatively, instead of the decrement of the valve opening of each regulating valve by one rank, the valve opening of each regulating valve may be decreased by an amount of decrease at which the flow rate ratios are varied due to the decrement by the same amount of variation. If the determination result in Step S1606 is NO, the process goes to Step S1608.

In Step S1608, the regulating valve controller 86 increments the valve opening of the regulating valve corresponding to the electronic unit 31D in the high-temperature state for which the valve opening increasing instruction is issued by one rank. For example, one rank may be 10%. For example, when the electronic unit 31D in the high-temperature state for which the valve opening increasing instruction is issued is the electronic unit 31Db (PIU-B) and the current valve opening of the regulating valve 65b is 60%, the regulating valve controller 86 increases the valve opening of the regulating valve 65b to 70%.

In Step S1610, the regulating valve controller 86 reads out the current valve opening of the regulating valve corresponding to the electronic unit 31D in the low-temperature state for which the valve opening decreasing instruction is issued, among the regulating valves 65a to 65d, in response to reception of the valve opening decreasing instruction.

In Step S1612, the regulating valve controller 86 determines whether the current valve opening of the regulating valve, acquired in Step S1610, is equal to a minimum valve opening (that is, 0%). If the determination result is YES, the process on the current cycle is terminated because the valve opening is not further decreased. However, in a modification, if the determination result in Step S1612 is YES, the regulating valve controller 86 may increment the valve opening of each of the regulating valves corresponding to the electronic units 31D other than the electronic unit 31D in the low-temperature state, among the regulating valves 65a to 65d, and the regulating valve 76D by one rank. Alternatively, instead of the increment of the valve opening of each regulating valve by one rank, the valve opening of each regulating valve may be increased by an amount of increase at which the flow rate ratios are varied due to the increment by the same amount of variation. If the determination result in Step S1612 is NO, the process goes to Step S1614.

In Step S1614, the regulating valve controller 86 decrements the valve opening of the regulating valve corresponding to the electronic unit 31D in the low-temperature state for which the valve opening decreasing instruction is issued by one rank. For example, when the electronic unit 31D in the low-temperature state for which the valve opening decreasing instruction is issued is the electronic unit 31Dc (PIU-C) and the current valve opening of the regulating valve 65c is 60%, the regulating valve controller 86 decreases the valve opening of the regulating valve 65c to 50%.

With the process illustrated in FIG. 16, the regulating valve controller 86 varies the valve opening of the regulating valve corresponding to the electronic unit 31D in the high-temperature state or the regulating valve corresponding to the electronic unit 31D in the low-temperature state, among the regulating valves 65a to 65d, in accordance with the valve opening increasing instruction or the valve opening decreasing instruction from the bookshelf-type unit side controller 32. When the valve opening of one of the regulating valves 65a to 65d is varied, the flow rate of the cooling passage corresponding to the regulating valve the valve opening of which is varied, among the cooling passages 61a to 61d, is varied. However, since the pump rotation speed controlling portion 82 functions in the above manner, the flow rate Mx of the monitoring control passage 72 is kept at the predetermined flow rate Mref even when the valve opening of one of the regulating valves 65a to 65d is varied. Accordingly, the flow rate of each cooling passage corresponding to the regulating valve the valve opening of which is not varied is not affected.

Although the regulating valves 65a to 65d are provided for all the cooling passages 61a to 61d in the fifth embodiment described above, the provision of the regulating valves 65a to 65d is not limited to this. The regulating valves may be provided only for part of the cooling passages 61a to 61d.

Although the flow rate monitoring unit 70D is provided in the fifth embodiment described above, the flow rate monitoring unit 70 according to the first embodiment may be provided, instead of the flow rate monitoring unit 70D. In this case, although the valve opening of the regulating valve 76D is not electronically controlled, the above control using the regulating valves 65a to 65d is still enabled.

The fifth embodiment described above may be combined with the second to fourth embodiments described above. For example, two or more pumps 54 may be provided or the flow rate monitoring unit 70D may be omitted and the pressure sensor 92 may be provided, instead of the flow rate monitoring unit 70D. Alternatively, the flow rate monitoring unit 70D may be omitted and the flowmeter 94 may be provided on the supply connection passage 62a, instead of the flow rate monitoring unit 70D.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A cooling control apparatus for an electronic apparatus in which a plurality of electronic units to be cooled are housed, the cooling control apparatus comprising:
a pump controller that controls a pump based on a detection value of a parameter indicating a flow rate of liquid refrigerant in one passage, among a plurality of passages, in a state in which the refrigerant for cooling the plurality of electronic units are discharged from the pump and is supplied to the plurality of passages via a supply manifold.

2. The cooling control apparatus according to claim 1,
wherein the pump controller controls the pump so that the flow rate of the refrigerant in the one passage is equal to a predetermined flow rate.

3. The cooling control apparatus according to claim 2,
wherein the plurality of passages are formed so that the flow rate of the refrigerant in the one passage and the flow rate of the refrigerant in a passage other than the one passage have a predetermined ratio, and
wherein the predetermined ratio correlates with relationship in power consumption between the plurality of electronic units.

4. The cooling control apparatus according to claim 3,
wherein at least part of the plurality of passages includes a flow rate regulating valve, the cooling control apparatus further comprising:
a valve controller that controls the flow rate regulating valve to vary the predetermined ratio.

5. The cooling control apparatus according to claim 1,
wherein the pump controller acquires a detection value by a flowmeter disposed in the one passage as the detection value of the parameter.

6. The cooling control apparatus according to claim 5,
wherein the plurality of passages include
a first passage in each of the plurality of passage, which is coupled to a return manifold via the plurality of electronic unit; and
a second passage that is coupled to the return manifold without passing through the plurality of electronic units, and
wherein the one passage is the second passage.

7. The cooling control apparatus according to claim 1,
wherein the pump controller acquires a detection value by a pressure sensor that detects pressure of the refrigerant in the supply manifold as the detection value of the parameter.

8. The cooling control apparatus according to claim 1,
wherein the pump controller controls a rotation speed of the pump.

9. An electronic apparatus comprising:
a rack;
a plurality of electronic units to be cooled, which are housed in the rack;
a pump;
a supply manifold to which liquid refrigerant discharged from the pump is supplied;
a return manifold;
a plurality of passages between the supply manifold and the return manifold; and
a pump controller that controls the pump based on a detection value of a parameter indicating a flow rate of the refrigerant in one passage, among the plurality of passages, in a state in which the refrigerant for cooling the plurality of electronic units are discharged from the pump and is supplied to the plurality of passages via the supply manifold.

10. The electronic apparatus according to claim 9,
wherein the pump controller controls the pump so that the flow rate of the refrigerant in the one passage is equal to a predetermined flow rate.

11. The electronic apparatus according to claim 9, further comprising:
a flowmeter disposed in the one passage,
wherein the pump controller acquires a detection value by the flowmeter as the detection value of the parameter.

12. The electronic apparatus according to claim 11,
wherein the plurality of passages include
a first passage in each of the plurality of passage, which passes through the plurality of electronic units; and
a second passage that does not pass through the plurality of electronic units, and
wherein the one passage is the second passage.

13. The electronic apparatus according to claim 9, further comprising:
a pressure sensor that detects pressure of the refrigerant in the supply manifold,
wherein the pump controller acquires a detection value by the pressure sensor as the detection value of the parameter.

14. The electronic apparatus according to claim 9,
wherein the pump includes two or more pumps, and
wherein the pump controller controls the two or more pumps so that the flow rate of the refrigerant in the one passage is equal to a predetermined flow rate.

15. A cooling control method for an electronic apparatus in which a plurality of electronic units to be cooled are housed, the cooling control method comprising:
controlling a pump based on a detection value of a parameter indicating a flow rate of liquid refrigerant in one passage, among a plurality of passages, in a state in which the refrigerant for cooling the plurality of electronic units are discharged from the pump and is supplied to the plurality of passages via a supply manifold.
